(19) United States
(12) Patent Application Publication
(10) Pub. No.: US 2012/0051508 A1
(43) Pub. Date: Mar. 1, 2012

(54) Grid for radiography and manufacturing method thereof, and radiation imaging system

(75) Inventor: Yasuhisa Kaneko, Kanagawa (JP)

(73) Assignee: FUJIFILM Corporation, Tokyo (JP)

(21) Appl. No.: 13/137,280

(22) Filed: Aug. 3, 2011

(30) Foreign Application Priority Data
Aug. 30, 2010 (JP) 2010-192357

(51) Int. Cl. G01N 23/04; H01L 31/18; G21K 1/00

(52) U.S. Cl. 378/62; 378/145; 438/71; 257/E31.092

(57) ABSTRACT

A gold colloidal solution is applied by dripping to a radio-transparent substrate having grooves with a high aspect ratio. The applied gold colloidal solution flows into the groove by capillarity, and is retained in the bottom of the groove. The radio-transparent substrate is heated from beneath by a laser beam at a part of the groove to which the gold colloidal solution has been applied, so the gold colloidal solution is vaporized and dried. Thus, gold colloidal particles remaining in the groove form a seed layer for electrolytic plating.

### BACKGROUND OF THE INVENTION

1. Field of the Invention

The present invention relates to a grid used in radiography, and a manufacturing method of the grid, and a radiation imaging system using the grid.

2. Description Related to the Prior Art

A radiation imaging system using the Talbot effect is devised as a type of radiation phase imaging, by which an image (hereinafter called phase contrast image) is obtained based on a phase change (angle change) of radiation transmitted through an object. For example, an X-ray imaging system using X-rays as the radiation is constituted of a first grid, a second grid, and an X-ray image detector. The first grid is disposed behind an object to be imaged. The second grid is disposed downstream from the first grid in an X-ray transmission direction by the Talbot distance, which is determined by a grid pitch of the first grid and a wavelength of the X-rays. The X-ray image detector is disposed behind the second grid. The X-rays transmitted through the first grid form a self image (fringe image) of the first grid by the Talbot effect at the position of the second grid. The self image is modulated by the phase change of the X-rays due to the presence of the object.

In the above X-ray imaging system, the second grid is overlaid on the self image of the first grid, to obtain a fringe image with modulated intensity. The phase contrast image of the object is obtained based on a change (phase shift) of the fringe image by the object. This is called a fringe scanning method. In the fringe scanning method, while the second grid is translationally moved (scanned) relative to the first grid in a direction approximately parallel to a surface of the first grid and approximately orthogonal to a grid direction of the first grid by a scan pitch that is an integral submultiple of the grid pitch, an image is captured at each scan position. Then, a differential phase image (corresponding to angular distribution of the X-rays refracted by the object) is obtained from a phase shift amount of intensity variation of pixel data of each pixel obtained by an X-ray image detector with respect to the scan positions. Integrating the differential phase image along a fringe scanning direction allows obtainment of the phase contrast image of the object.

The first and second grids have such a configuration that X-ray absorbing portions extending in a direction orthogonal to the X-ray transmission direction are arranged at a predetermined pitch into stripes in a direction orthogonal to both the X-ray transmission direction and the extending direction. The arrangement pitch of the X-ray absorbing portions is determined by a distance between an X-ray focus and the first grid and a distance between the first and second grids, and is approximately 2 to 20 μm. Each of the X-ray absorbing portions of the second grid requires a high aspect ratio, e.g. a thickness of approximately 100 μm in the X-ray transmission direction, in order to acquire high X-ray absorptivity.

In a well-known conventional method for manufacturing a grid for phase imaging, grooves are formed in a silicon substrate by etching or the like. Then, a seed layer for metal plating is formed in the bottom of the grooves out of metal such as copper or titanium. After that, using the seed layer as an electrode, an X-ray absorbing material such as gold is charged into the grooves by electrolytic plating (refer to Japanese Patent No. 4642818, for example). Also, there is known a method in which gold paste is embedded in the grooves to form the X-ray absorbing portions (refer to Japanese Patent Laid-Open Publication No. 2009-282322).

To form the seed layer in the bottom of the grooves, as described in the Japanese Patent No. 4642818, it is conceivable to use a method of vacuum evaporation. However, the evaporated metal adheres not only to the bottom but also to side walls of the grooves. Thus, a contrivance to prevent the adhesion of the metal to the side walls, a step for removing the metal adhering to the side walls, or the like, becomes necessary. This contrivance or step causes increase in manufacturing costs and reduction in throughput. According to the Japanese Patent Laid-Open Publication No. 2009-282322, on the other hand, the gold paste is used as the X-ray absorbing material. Paste refers to a material having a viscosity over 1 PaS, generally having a viscosity of 100 to 1000 PaS. Therefore, it is difficult to embed the gold paste having a high viscosity in the minute grooves having a width of several μm to a depth of the order of 100 μm, for example, as well as charging the gold paste only into the bottom of the grooves to form the seed layer for the electrolytic plating.

### SUMMARY OF THE INVENTION

An object of the present invention is to provide a manufacturing method of a grid by which a seed layer for electrolytic plating is easily formed in the bottom of grooves with a high aspect ratio.

To achieve the above and other objects, a grid for radiography according to the present invention includes a plurality of radiation absorbing portions and a plurality of radio-transparent portions. Each of the radiation absorbing portions includes a first layer and a second layer. The first layer is made of metal colloidal particles having high radiation absorptivity. The second layer is provided on the first layer, and is made of metal having high radiation absorptivity.

The first and second layers are preferably embedded in each of plural grooves provided in a radio-transparent substrate, or preferably provided on the radio-transparent substrate. The metal colloidal particles are preferably gold colloidal particles.

A manufacturing method of a grid for radiography includes the steps of forming a plurality of grooves in a radio-transparent substrate, charging into each of the grooves a metal colloidal solution containing metal colloidal particles having high radiation absorptivity, heating the substrate at least at a portion of the groove charged with the metal colloidal solution until the metal colloidal solution is dried to form a seed layer out of the metal colloidal particles remaining in the groove, and embedding a radiation absorbing material in each of the grooves by electrolytic plating using the seed layer as an electrode to form radiation absorbing portions.

In the charging step of the metal colloidal solution, the metal colloidal solution is preferably applied to the substrate, and the metal colloidal solution preferably flows into the groove. After the forming step of the grooves, the substrate is preferably subjected to processing for improving wettability. In the heating step of the substrate, a laser beam is preferably applied to the substrate from a side opposite to the grooves.

A radiation imaging system according to the present invention includes a radiation source for emitting radiation, a first grid, a second grid, a third grid disposed between the radiation source and the first grid, and a radiation image detector. The first grid transmits the radiation and forms a fringe image. The second grid modulates intensity of the fringe image. The third grid partly blocks the radiation emitted from the radiation source so as to form a plurality of linear light sources. The radiation image detector detects the fringe image after the intensity is modulated by the second grid. At least one of the first to third grids is the grid described above.

According to the grid of the present invention, the radiation absorbing portion includes the first layer made of the metal colloidal particles having low stress. Thus, the grid is flexible and resistant to external force. The radiation absorbing portions may be provided in the grooves formed in the substrate, or may be provided on the substrate. Use of the gold colloidal particles as the metal colloidal particles allows for improved radiation absorptivity.

According to the manufacturing method of the grid of the present invention, the seed layer for electrolytic plating is formed by charging the metal colloidal solution into the groove. Thus, it is possible to easily form the seed layer at low cost, as compared to the case of forming the seed layer by evaporation or the like. The metal colloidal solution flows into the groove by capillarity. Therefore, the metal colloidal solution can be properly charged into the groove having a high aspect ratio. Also, the substrate is subjected to the processing for improving wettability in order to charge the metal colloidal solution into the groove more surely. Furthermore, the substrate can be heated by a laser selectively only the part of the groove having been charged with the metal colloidal solution.

The radiation imaging system according to the present invention can take a radiographic image with high image quality due to the use of the above-described grid.

### BRIEF DESCRIPTION OF THE DRAWINGS

For more complete understanding of the present invention, and the advantage thereof, reference is now made to the following descriptions taken in conjunction with the accompanying drawings, in which:

FIG. 1 is a schematic view of an X-ray imaging system;

FIG. 2A is a plan view of a second grid;

FIG. 2B is a sectional view taken along the line A-A of FIG. 2A;

FIGS. 3A to 3D are explanatory views showing a manufacturing procedure of the second grid;

FIG. 4A is a top plan view of a radio-transparent substrate in which grooves are formed;

FIG. 4B is a sectional view taken along the line B-B of FIG. 4A;

FIGS. 5A and 5B are explanatory views showing a step of charging a metal colloidal solution into the grooves of the radio-transparent substrate;

FIG. 6 is an explanatory view for explaining that the metal colloidal solution is charged into each of plural areas into which the radio-transparent substrate is divided;

FIG. 7 is a schematic view that explains electrolytic plating for charging an X-ray absorbing material into the grooves;

FIG. 8 is a sectional view of the thinned radio-transparent substrate;

FIG. 9 is a sectional view in which the radio-transparent substrate is removed at parts between the X-ray absorbing portions;

FIG. 10 is a plan view of a grid constituted of plural small grids; and

FIG. 11 is a schematic view of an X-ray imaging system using curved grids.

### DESCRIPTION OF THE PREFERRED EMBODIMENTS

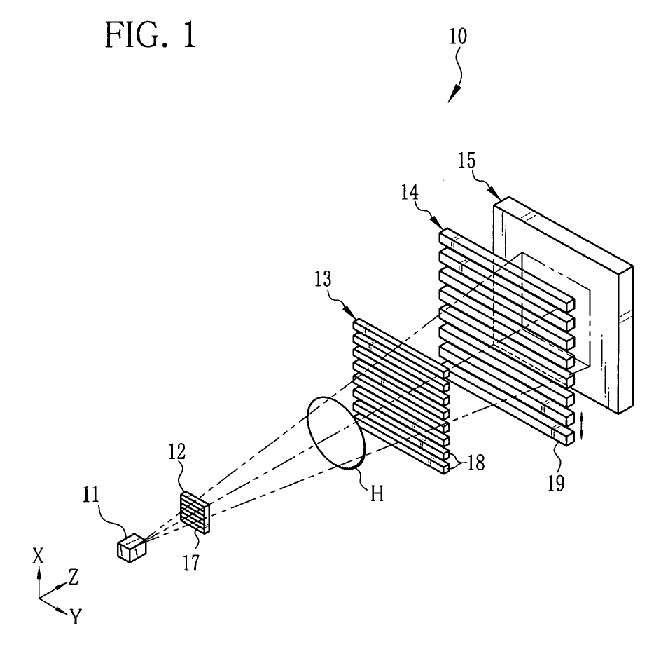

As shown in FIG. 1, an X-ray imaging system 10 according to the present invention is constituted of an X-ray source 11, a source grid 12, a first grid 13, a second grid 14, and an X-ray image detector 15. The X-ray source 11 applies X-rays to an object H disposed in a Z direction. The source grid 12 is opposite to the X-ray source 11 in the Z direction. The first grid 13 is disposed in parallel with the source grid 12 at a predetermined distance away from the source grid 12 in the Z direction. The second grid 14 is disposed in parallel with the first grid 13 at another predetermined distance away from the first grid 13 in the Z direction. The X-ray image detector 15 is opposite to the second grid 14. As the X-ray image detector 15, a flat panel detector (FPD) using semiconductor circuitry is employed, for example.

The source grid 12, the first grid 13, and the second grid 14 are X-ray absorption grids having plural X-ray absorbing portions 17, 18, and 19, respectively. The X-ray absorbing portions 17, 18, and 19 extend linearly in a Y direction orthogonal to the Z direction, and are periodically arranged at a predetermined pitch along an X direction orthogonal both the Z and Y directions into stripes. The X-ray absorbing portions 17, 18, and 19 absorb the X-rays, while X-ray transparent portions provided between the X-ray absorbing portions 17, 18, and 19 transmit the X-rays. The first and second grids 13 and 14 linearly project the X-rays transmitted through the X-ray transparent portions.

The configuration of the X-ray absorbing portions will be hereinafter described, taking the second grid 14 as an example. Note that, the source grid 12 and the first grid 13 have configuration similar to that of the second grid 14 except for the width, the pitch, the thickness in an X-ray transmission direction, and the like of the X-ray absorbing portions 17 and 18, so detailed description thereof will be omitted.

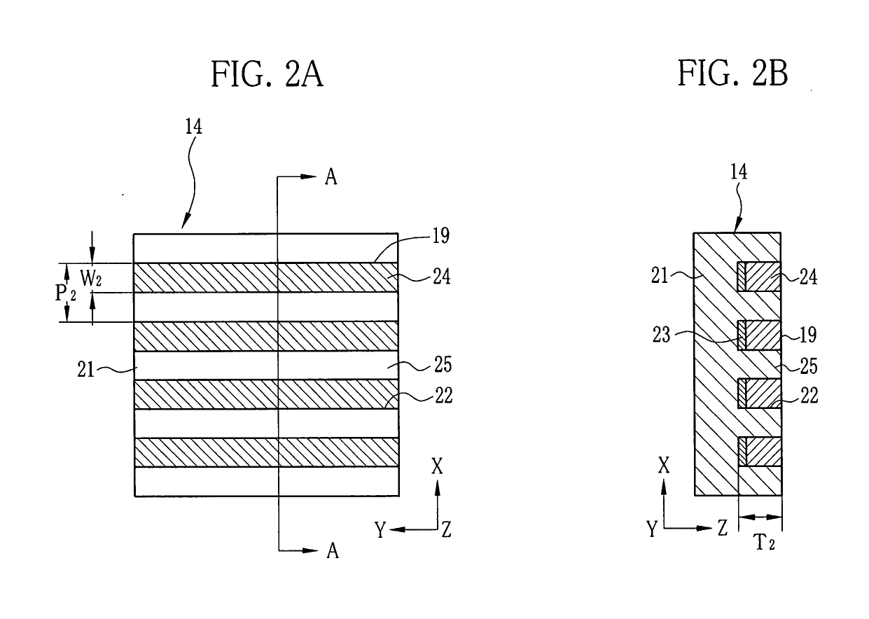

As shown in FIGS. 2A and 2B, the second grid 14 includes a radio-transparent substrate 21 made of an X-ray transparent material such as silicon, plural grooves 22 extending in the Y direction and arranged at a predetermined pitch in the X direction, a seed layer 23 provided in the bottom of each groove 22, and an X-ray absorbing material 24 charged into each groove 22. The X-ray absorbing portion 19 is composed of the groove 22, the seed layer 23, and the X-ray absorbing material 24. The X-ray absorbing material 24 is made of an X-ray absorptive metal, e.g. gold, platinum, or the like. A plurality of partition walls 25, which partition the grooves 22, function as the X-ray transparent portions.

The width W₂ and pitch P₂ of the X-ray absorbing portions 19 depend on the distance between the source grid 12 and the first grid 13, the distance between the first grid 13 and the second grid 14, the pitch of the X-ray absorbing portions 18 of the first grid 13, and the like. The width W₂ of the X-ray absorbing portions 19 is approximately 2 to 20 μm, and the pitch P₂ thereof is approximately 4 to 40 μm. To improve X-ray absorptivity, the thicker the thickness T₂ of the X-ray absorbing portions 19 in the Z direction, the better. However, the thickness T₂ of the X-ray absorbing portions 19 is preferably in the order of 100 μm, for example, in consideration of vignetting of a cone beam of X-rays emitted from the X-ray source 11. In this embodiment, the width W₂ is 2.5 μm, and the pitch P₂ is 5 μm, and the thickness T₂ is 100 μm, by way of example.

The seed layer 23 is used as an electrode when charging the X-ray absorbing material 24 into the grooves 22 by electrolytic plating. The seed layer 23 contains plural kinds of X-ray absorptive metals, and is mainly made of gold colloidal particles, for example. The gold colloidal particles are charged into the grooves 22 in a state of a gold colloidal solution, which contains the dispersed gold colloidal particles. Then, the gold colloidal solution is heated and dried, so that the gold colloidal particles remain in the grooves 22 and form the seed layer 23. The gold colloidal solution contains the plural kinds of X-ray absorptive metals including copper (Cu), bismuth (Bi), and the like, in addition to the gold colloidal particles. These metals remain in the grooves 22 together with the gold colloidal particles, and serve to improve the X-ray absorptivity of the seed layer 23. Note that, the gold colloidal particles are bonded together more weakly than particles bonded by gold plating or the like, and hence have low stress. For this reason, even if some sort of external force is exerted on the second grid 14, the gold colloidal particles can absorb the external force. Thereby, the second grid 14 is hard to damage. Also, use of the gold colloidal particles gives a flexible property to a grid. Thus, a grid having a converging configuration can be easily obtained.

Taking the second grid 14 as an example, a manufacturing method of a grid for radiography according to the present invention will be described. Note that, the source grid 12 and the first grid 13 are manufactured by the same or similar method, so detailed description thereof will be omitted.

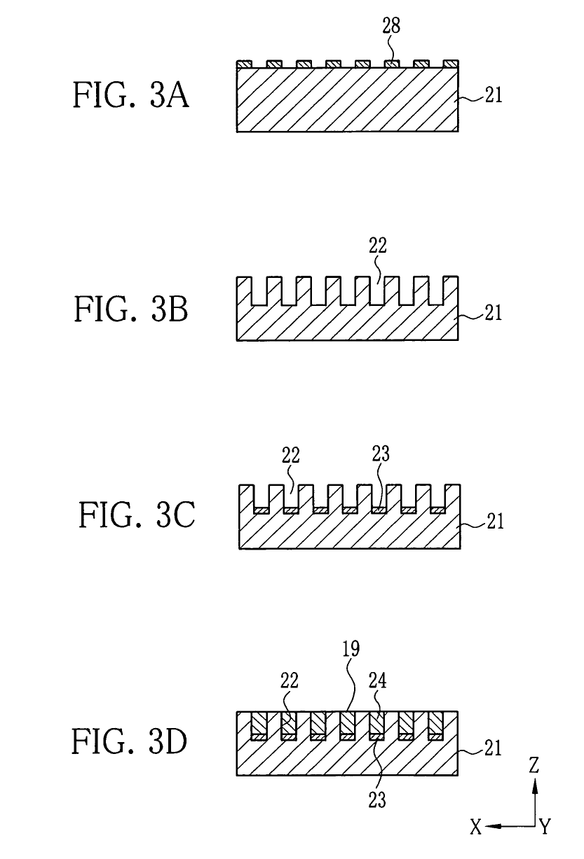

As shown in FIG. 3A, in a first step of manufacture of the second grid 14, an etching mask 28 is formed on a top surface of the silicon radio-transparent substrate 21, using a conventional photolithography technique. The etching mask 28 is formed in stripes, linearly extending in the Y direction and periodically arranged at a predetermined pitch in the X direction.

As shown in FIG. 3B, in the next step, the plural grooves 22 are formed in the radio-transparent substrate 21 by dry etching using the etching mask 28. To form the grooves 22 into a high aspect ratio having a width of several μm and a depth of 100 μm, for example, Bosch process, cryo process, or the like is used in the dry etching. A photosensitive resist may be used instead of the silicon substrate, and grooves may be formed by exposure to synchrotron radiation.

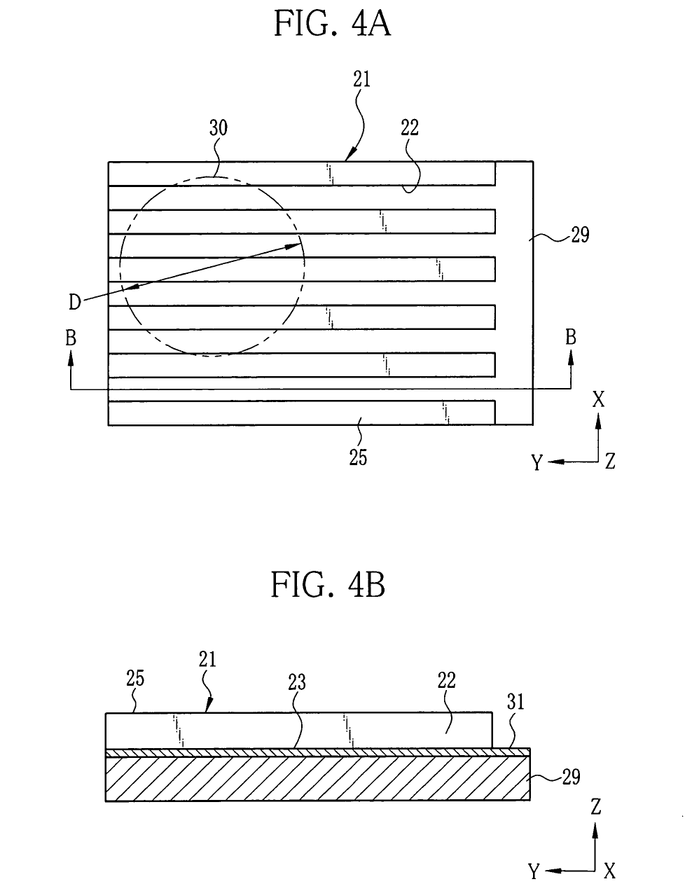

FIG. 4A is a plan view of the radio-transparent substrate 21 having the plural grooves 22 formed therein. FIG. 4B is a sectional view taken along the line B-B of FIG. 4A. A ledge 29 is formed on one side of the radio-transparent substrate 21 such that a top surface of the ledge 29 continuously becomes flush with the bottom surface of the grooves 22. The ledge 29 is formed with the grooves 22 by the dry etching using the etching mask 28.

In the next step, as shown in FIG. 3C, the seed layer 23 is formed in the bottom of the grooves 22. The seed layer 23 is formed by applying the gold colloidal solution to a surface of the radio-transparent substrate 21 on a side of the grooves 22 and drying the gold colloidal solution. The used gold colloidal solution contains the gold colloidal particles of the order of 10 to 1000 Å dispersed in an arbitrary homogeneous solvent. The gold colloidal solution preferably has a gold content of the order of 50 mass % and a viscosity of 1 PaS or less, for example. Instead of the gold colloidal solution, a platinum colloidal solution or a mixture colloidal solution of the plural kinds of X-ray absorptive metals e.g. gold and platinum may be used.

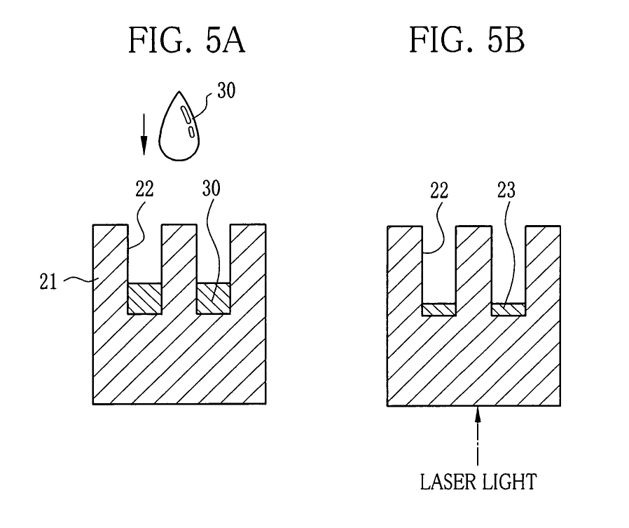

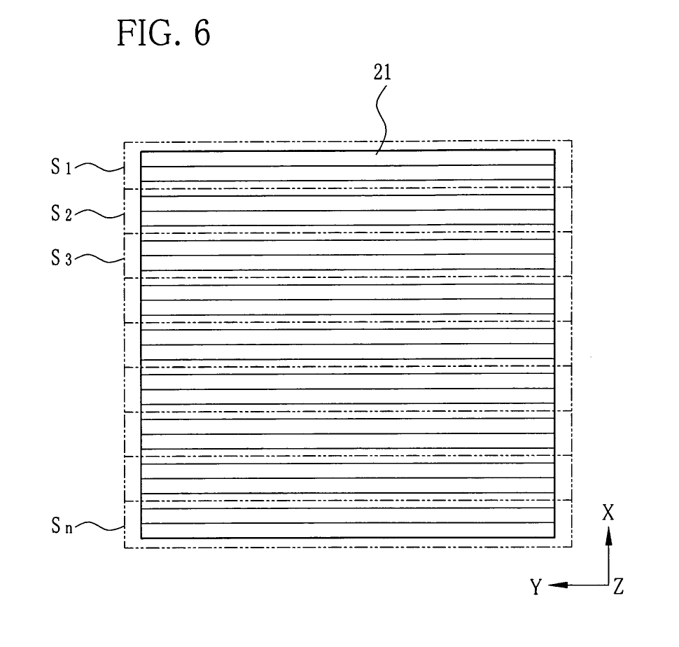

As shown in FIG. 5A, a gold colloidal solution 30 is applied to the radio-transparent substrate 21 by a device for dripping or spraying minute liquid droplets, such as an inkjet head, sprayer, or dispenser. In the case of using the inkjet head or dispenser, as shown in FIG. 4A, the size D of the droplet of the gold colloidal solution 30 to be applied to the radio-transparent substrate 21 is 10 to 50 μm, for example. The radio-transparent substrate 21 is divided into plural areas S1 to Sn in an arrangement direction of the grooves 22, as shown in FIG. 6, and the gold colloidal solution 30 is applied from area to area. The gold colloidal solution 30 applied to the radio-transparent substrate 21 gets into the grooves 22 by capillarity, and is retained in the bottom of the grooves 22. The gold colloidal solution 30 is applied in such an amount that the thickness of the gold colloidal particles remaining in the grooves 22 after drying the gold colloidal solution 30 is of the order of 0.1 to 10 μm, for example. Note that, after the grooves 22 are formed, the radio-transparent substrate 21 may be subjected to wettability improvement processing, such as primer processing, UV cleaning, or plasma cleaning, for ease of a flow of the gold colloidal solution 30 into the grooves 22. Note that, in the case of applying the gold colloidal solution 30 by the sprayer, the gold colloidal solution 30 may be sprayed on all areas at a time.

As shown in FIG. 5B, after the gold colloidal solution 30 is applied to the radio-transparent substrate 21, the radio-transparent substrate 21 is heated to the order of 150 to 300° C. at the solution applied areas. The solvent of the gold colloidal solution 30 is vaporized into gas by heating. The gold colloidal particles are partly or totally bonded by heating in the grooves 22, and serve to improve electric conductivity. To heat the radio-transparent substrate 21, for example, a laser beam is applied from beneath to at least one of the areas S1 to Sn to which the gold colloidal solution 30 has been applied. Note that, some time is required by the gold colloidal solution 30 applied to the radio-transparent substrate 21 for flowing into the bottom of the grooves 22. Therefore, it is preferable that the radio-transparent substrate 21 is heated after a lapse of predetermined time from the application of the gold colloidal solution 30.

As shown in FIG. 4B, a seed layer is formed not only in the grooves 22 as the seed layer 23 but also concurrently on the top surface of the ledge 29. This seed layer 31 continues to every seed layer 23 of every groove 22. The seed layer 31 functions as a terminal layer to which a current terminal is connected to flow an electric current into every seed layer 23 during the electrolytic plating.

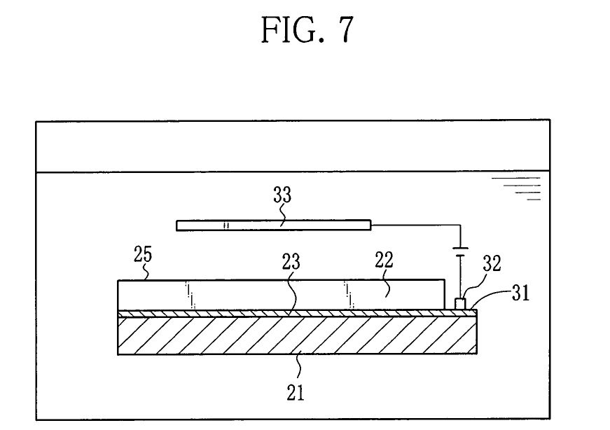

As shown in FIG. 3D, in the next step, the X-ray absorbing material 24 is charged into the grooves 22 by the electrolytic plating, to form the X-ray absorbing portions 19. As shown in FIG. 7, the radio-transparent substrate 21 is submerged in a plating solution with a current terminal 32 connected to the terminal layer 31. Another electrode (positive electrode) 33 is disposed oppositely to the radio-transparent substrate 21. By flowing an electric current between the terminal layer 31 and the electrode 33, metal ions contained in the plating solution are deposited on the grooves 22 of the radio-transparent substrate 21. In such a manner, the grooves 22 are filled with gold.

Next, the operation of the X-ray imaging system 10 will be described. The X-rays emitted from the X-ray source 11 are partly blocked by the X-ray absorbing portions 17 of the source grid 12, to form many linear X-ray beams with a reduced effective focus size in the X direction. When the X-ray beams formed by the source grid 12 transmit through the object H, phase difference occurs in the X-ray beams. After that, each X-ray beam forms a fringe image by transmitting through the first grid 13. The fringe image contains transmission phase information of the object H, which depends on the refractivity of the object H and a transmission optical path of the X-ray beam. The fringe images of the individual X-ray beams are projected onto the second grid 14, and overlap one another at a position of the second grid 14 so as to form a fringe image with strengthened intensity. Therefore, it is possible to improve the image quality of a phase contrast image without reducing the intensity of the X-rays.

The intensity of the fringe image is modulated by the second grid 14, and detected by a fringe scanning method, for example. In the fringe scanning method, the second grid 14 is translationally moved in the X direction relative to the first grid 13 along a grid surface with respect to an X-ray focus by a scan pith that is an integral submultiple of the grid pitch, e.g. one-fifth of the grid pitch. At each scan position, the X-rays are applied from the X-ray source 11 to the object H, and the X-ray image detector 15 detects the intensity of the fringe image modulated by the second grid 14. Then, a differential phase image is obtained from a phase shift amount (a shift amount in phase between in the presence of the object H and in the absence of the object H) of pixel data of each pixel. Integrating the differential phase image along a fringe scanning direction allows for obtainment of the phase contrast image of the object H.

According to the grid of this embodiment, as described above, the seed layer 23 is formed of the gold colloidal solution containing the plural kinds of X-ray absorptive metals such as bismuth in addition to gold, and has high X-ray absorptivity. In addition, since the gold colloidal particles have low stress, the grid is flexible and resistant to external force. Furthermore, in a manufacturing method of the grid according to this embodiment, the seed layer 23 is formed in the bottom of the grooves 22 with the high aspect ratio only by the two steps of application and heating of the gold colloidal solution 30. Thus, it is possible to form the seed layer 23 at low cost and with high throughput, in comparison with the case of forming a seed layer by vacuum evaporation.

In the above embodiment, the structure, manufacturing method, effect, and the like are described with taking the second grid 14 as an example, but the same goes for the source grid 12 and the first grid 13. Note that, the gold colloidal particles are sensitive to heat. For this reason, if the source grid 12 becomes hot by application of the X-rays, a conventional source grid is preferably used as the source grid 12 instead of the grid of this embodiment.

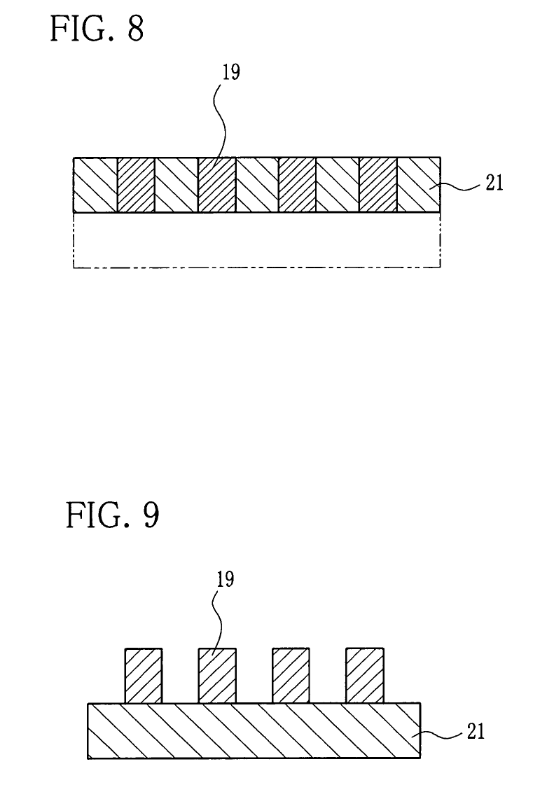

As shown in FIG. 8, after the X-ray absorbing portions 19 are formed, the bottom of the radio-transparent substrate 21 may be polished and thinned by CMP or the like. As shown in FIG. 9, after the X-ray absorbing portions 19 are formed, parts between the X-ray absorbing portions 19 may be removed by etching or the like, to improve X-ray transparency of the grid.

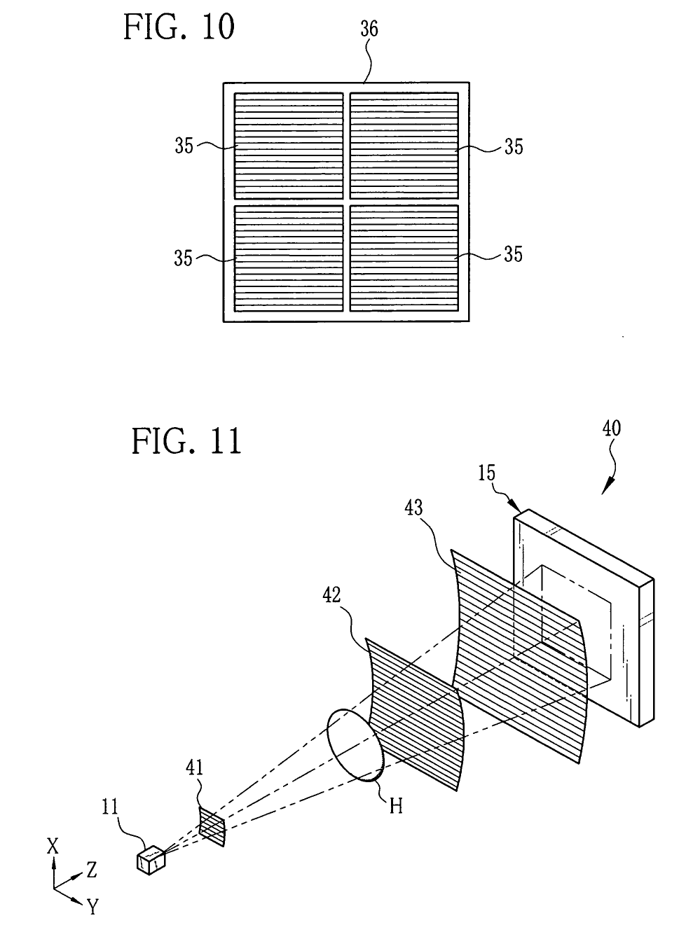

If the size of the grid to be manufactured by the present invention is small, a large grid 36 may be composed of a plurality of small grids 35 arranged as shown in FIG. 10. The grid of the present invention may be applied to a source grid 41, a first grid 41, and a second grid 43 with converging configuration, each of which is curved into a concave shape along an extending direction of an X-ray absorbing portions, as shown in FIG. 11, to reduce vignetting of a cone beam of X-rays. According to the grid of the present invention, since the seed layer 23 is made of the gold colloidal particles with low stress, the grid is hard to damage due to curvature.

Furthermore, in the above embodiments, the gold colloidal solution 30 is charged into the grooves 22 using the capillarity, but the gold colloidal solution 30 may be directly dripped into the groove 22 using an inkjet head or the like that can eject a droplet roughly the size of the width of the groove 22.

In the above embodiments, the X-rays transmitted through the first and second grids 13 and 14 are linearly projected.

However, the grid of the present invention may be applied to configuration in which the grid diffracts the X-rays and causes the Talbot effect (refer to U.S. Pat. No. 7,180,979 and Applied Physics Letters Vol. 81, No. 71, page 3287, written by C. David et al. on October 2002). Note that, in this case, the distance between the first and second grids 13 and 14 has to be set at the Talbot distance. Also, in this case, a phase grid may be used as the first grid 13. The phase grid used instead of the first grid 13 forms a fringe image (self image) occurring by the Talbot effect at a position of the second grid 14.

In the above embodiments, the second grid 14 is moved relative to the first grid 13. However, as described in US Patent Application Publication No. 2010/0290590, while first and second grids are fixed, a fringe image with intensity modulated by the second grid may be detected. The fringe image may be subjected to Fourier transform processing or the like, to produce a differential phase image.

The above embodiments are described taking X-rays as an example of radiation, but the present invention is applicable to a grid for radiography using other kinds of radiation including α-rays, β-rays, γ-rays, electron rays, ultraviolet rays, and the like. The present invention is also applicable to an anti-scatter grid for removing the radiation scattered by an object, when the radiation transmits through the object. Furthermore, each of the above embodiments may be combined with each other as long as no contradiction arises.

Although the present invention has been fully described by the way of the preferred embodiment thereof with reference to the accompanying drawings, various changes and modifications will be apparent to those having skill in this field. Therefore, unless otherwise these changes and modifications depart from the scope of the present invention, they should be construed as included therein.

What is claimed is:

1. A grid for radiography comprising:
(A) a plurality of radiation absorbing portions for absorbing radiation, each of said radiation absorbing portions including:
a first layer made of metal colloidal particles having high radiation absorptivity; and
a second layer provided on said first layer and made of a metal having high radiation absorptivity;
(B) a plurality of radio-transparent portions for transmitting said radiation.

2. The grid according to claim 1, wherein said first and second layers are embedded in each of plural grooves formed in a radio-transparent substrate.

3. The grid according to claim 1, wherein said radiation absorbing portions are provided on a radio-transparent substrate.

4. The grid according to claim 1, wherein said metal colloidal particles are gold colloidal particles.

5. A manufacturing method of a grid for radiography comprising the steps of:
forming a plurality of grooves in a radio-transparent substrate;
charging a metal colloidal solution into each of said grooves, said metal colloidal solution containing metal colloidal particles having high radiation absorptivity;
heating said substrate at least at a portion of said groove charged with said metal colloidal solution until said metal colloidal solution is dried, to form a seed layer out of said metal colloidal particles remaining in said groove; and
embedding a radiation absorbing material in each of said grooves by electrolytic plating using said seed layer as an electrode, to form radiation absorbing portions.

6. The manufacturing method according to claim 5, wherein in the charging step of said metal colloidal solution, said metal colloidal solution is applied to said substrate, and said metal colloidal solution flows into said groove.

7. The manufacturing method according to claim 6, wherein after the forming step of said grooves, said substrate is subjected to processing for improving wettability.

8. The manufacturing method according to claim 5, wherein in the heating step of said substrate, a laser beam is applied to said substrate from a side opposite to said grooves.

9. A radiation imaging system comprising:
a radiation source for emitting radiation;
a first grid for transmitting said radiation and forming a fringe image;
a second grid for modulating intensity of said fringe image;
a third grid disposed between said radiation source and said first grid, for partly blocking said radiation emitted from said radiation source so as to form a plurality of linear light sources; and
a radiation image detector for detecting said fringe image after said intensity is modulated by said second grid; and
wherein at least one of said first to third grids includes:
(A) a plurality of radiation absorbing portions for absorbing said radiation, each of said radiation absorbing portions includes:
a first layer made of metal colloidal particles having high radiation absorptivity; and
a second layer provided on said first layer and made of a metal having high radiation absorptivity;
(B) a plurality of radio-transparent portions for transmitting said radiation.
